(19) United States
(12) Patent Application Publication
(10) Pub. No.: US 2020/0209738 A1
(43) Pub. Date: Jul. 2, 2020

(54) SYSTEM AND METHOD FOR ENHANCED STEREOLITHOGRAPHY 3D PRINTING

(71) Applicant: NuSpot Technologies, LLC, Charlotte, NC (US)

(72) Inventor: Paolo BATONI, Charlotte, NC (US)

(21) Appl. No.: 16/658,643

(22) Filed: Oct. 21, 2019

Related U.S. Application Data
(63) Continuation-in-part of application No. 16/237,873, filed on Jan. 2, 2019.

(51) Int. Cl. G03F 7/00; B29C 64/264; B29C 64/124; G02B 5/18; G02B 5/32

(52) U.S. Cl. CPC G03F 7/0037; B29C 64/264; B33Y 30/00; G02B 5/1838; G02B 5/32; B29C 64/124

(57) ABSTRACT

A system for 3D printing utilizing non-UV, near-UV, and/or UV photons with or without engineered angular momentum, which may be organized as shaped flux or flux shaping structures of non-UV photons, near-UV photons, and/or UV photons, the system comprising: one or more of a coherent source, a partially-coherent source, and an incoherent source of one or more of non-UV photons, near-UV photons, and UV photons; and one or more flux shaping structures or angular momentum generators, with or without flux shaping, configured to impart the one or more of the non-UV photons, the near-UV photons, and the UV photons with one or more of spin angular momentum (SAM) and orbital angular momentum (OAM).

### CROSS-REFERENCE TO RELATED APPLICATIONS

The present patent application/patent is a continuation-in-part (CIP) of co-pending U.S. patent application Ser. No. 16/237,873, filed on Jan. 2, 2019, and entitled “SYSTEM AND METHOD FOR ENHANCED STEREOLITHOGRAPHY 3D PRINTING,” the contents of which are incorporated in full by reference herein.

### STATEMENT OF GOVERNMENT SUPPORT

The present invention was made with U.S. Government support pursuant to Award No. 140D6318C0009 by the Defense Advanced Research Projects Agency (DARPA). Accordingly, the U.S. Government may have certain rights herein.

### FIELD OF THE INVENTION

The present invention relates generally to systems and methods for enhancing stereolithography (SLA) 3D printing by using super-resolved ultraviolet (UV) and/or near-UV radiation, and near-UV and/or UV photons of electromagnetic radiation with engineered angular momentum. Additionally, the present invention relates to systems and methods for using UV and near-UV photons, or combination of photons including UV photons with engineered angular momentum, to treat organic and inorganic substances such as photolymers, resins, plastics, photoinitiators, monomers, oligomers, and their combinations. Furthermore, the present invention relates to systems and methods for using super-resolved UV and/or near-UV radiation provided in the form of a flux or beam having a cross-section, or features smaller than said near-UV and/or UV radiation, or smaller than the cross-section of the emitting source to decrease the size of the minimum feature in nanometer range, and increase accuracy and precision of 3D printed objects and surfaces.

### BACKGROUND OF THE INVENTION

It is well known to those of ordinary skill in the art that stereolithography (using a Stereo Lithography Apparatus, or SLA) is form of additive manufacturing that makes use of electromagnetic radiation to selectively convert materials in a liquid form into solid parts epitaxially, or one layer upon another layer. This kind of additive manufacturing is also commonly known as 3D printing.

The term “additive manufacturing” (AM) is manufacturing method that is based on creating objects from a digital model by structuring materials using an additive process of sequential layering.

the SLA process was first introduced in 1981 by Dr. Hideo Kodama of the Nagoya Municipal Industrial Research Institute in Nagoya, Japan. Dr. Kodama first conceived and published work related to the manufacturing of a printed solid model as the fundamental block for additive manufacturing.

The term stereolithography was coined in 1983 by Charles W. Hull who designed and realized the first 3D printer, filed a patent for the technology in 1984, and co-founded 3D Systems Corp. to commercialize it in 1986, after the technology was patented. Hull's method allowed the creation of a 3D object by sequentially printing, one on top of another, thin layers of a material that is curable by means of ultraviolet (UV) electromagnetic radiation. Later on this description was extended to any material capable of solidification or alteration of its original physical state.

3D printing technology comprises three main phases: [1] modeling, [2] printing, and [3] finishing. In the [1] modeling phase, a digital 3D object is processed in a series of sequential cross-sections that will comprise a virtual model. In the [2] printing phase, the virtual model consisting of sequential cross sections is converted into machine instruction for the 3D printer, which will deposit layer of UV curable material onto a substrate. In order to achieve better accuracy and precision a 3D printed object is printed in a larger size and a lower resolution than the final desired one. During the [3] finishing phase, supplemental material may be removed using a subtractive process at higher resolution to obtain the 3D printed object in the desired size and surface finish.

3D printing technology and AM today use a wide range of processes, layering, materials, and technologies. In addition to SLA 3D printers, other less prevalent 3D printing technologies are [1] inkjet head and powder bed 3D printers, [2] selective laser sintering (SLS) 3D printers, [3] direct metal laser sintering (DMLS) 3D printers, [4] photolymers injecting 3D printers, and [5] fused deposition modeling (FDM) 3D printers.

Powder bed and inkjet 3D printers typically use ceramic powder to create objects, which are then thermally cured to improve mechanical properties and surface finish. With this kind of 3D printing, a thin layer of ceramic powder is dispersed throughout a sacrificial substrate, rolled out evenly, and finally sprayed with fine binder droplets. Sequential layers are deposited, one on top of another, so that the desired object is printed epitaxially.

SLS 3D printers deposit thin layers of finely powdered plastics such as nylon, which is consequentially melted by a laser beam scriber following the mapped pattern determined for that specific layer. Sequential layers are deposited, one on top of another, so that the desired object is printed epitaxially.

DMLS 3D printers deposit thin layers of finely powdered metals (typically titanium), which is consequentially melted by a laser beam scribe following the mapped pattern determined for that specific layer. Sequential layers are deposited, one on top of another, so that the desired object is printed epitaxially.

Photolymers injecting 3D printers deposit thin layers of resin, which is then solidified with UV electromagnetic radiation. Sequential layers are deposited and then solidified, one on top of another, so that the desired object is printed epitaxially.

FDM 3D printers feed a continuous filament of a thermoplastics material through a heated extruder head. Molten material is extruded and deposited on the growing object. The XYZ movement of the extruding head is controlled by computer. Sequential layers are deposited, one on top of another, so that the desired object is printed epitaxially.

SLA 3D printers are based on a technology known as vat photo polymerization, and their functionality is hinged on the use a source of UV electromagnetic radiation such a Laser Diode, or a projector, which is used to cure liquid resin into a hardened solid. Currently various systems are differentiated by the arrangement of the UV radiation source, the resin tank, and the substrate upon which the object is printed epitaxially. Two of the most recurrent hardware configurations are shown in FIG. 1: [A] Inverted SLA system, and [B] Right-Side Up Sla system.

In an Inverted SLA system configuration [A], the printed part [A][1] is epitaxially fabricated “up-side down” (against the direction of gravity) via a sacrificial support [A][2] onto a non-stick build platform [A][4] upon which the resin [A][3], can be irradiated with UV electromagnetic radiation. This method requires that the resin is contained within a tank [A][9] with a UV transparent bottom. The build platform is lowered into the resin tank until the former leaves a vertical displacement equal to the desired layer height. Electromagnetic radiation [A][8] provided by a UV source (typically a Laser Diode) [A][5] is directed to the correct coordinates by a series of galvanometers [A][6] onto a X-Y scanning mirror [A][7]. Upon absorbing the required UV dose, the resin cures into a solid. Only the resin exposed by the UV radiation will be cured. Therefore the UV radiation beam acts a scriber; the diameter of the UV beam size determines the size of the smaller feature that can be printed. The build platform is the moved upward to leave another vertical displacement equal to the desired layer thickness, and a new layer or resin is UV scribed and cured. The process is repeated, building one layer onto another, until the 3D printed object is complete. In a Right-Side Up SLA system configuration [B], the printed part [B][2] is epitaxially fabricated “up-side up” (in the direction of gravity) via a sacrificial support onto a non-stick build platform [B][4], which is submerged into a large tank [B][6] filled with resin [B][3]. Electromagnetic radiation [B][7] provided by a UV source (typically a Laser Diode) [B][10] is directed to the correct coordinates by a series of lenses [B][9] and a X-Y scanning mirror [B][8] onto the surface of the resin. Upon absorbing the required UV dose, the resin cures into a solid. Only the resin exposed by the UV radiation will be cured. Therefore the UV radiation beam acts a scriber; the diameter of the UV beam size determines the size of the smaller feature that can be printed. The build platform is then lowered by a displacement equal to desired layer thickness, and a sweeper [B][1] refreshes the surface of the resin to expose fresh material. The process is repeated, one layer on top of another, until the 3D object is built.

SLA 3D printers use a source of UV electromagnetic radiation such a Laser Diode, or a projector, which is used to cure liquid resin (photo-polymer) into a hardened solid. This process is known photo-polymerization, which is illustrated in FIG. 2. A photo-polymer resin is a polymer that changes its properties when irradiated with electromagnetic radiation in the UV region of the electromagnetic spectrum. The kinds photo-polymer resins used in SLA 3D printer are designed to harden as a result of chemical cross-linking when exposed to UV radiation, a phenomenon known as UV curing. As illustrated in Error! Reference source not found.[A], an untreated photo-polymer is depicted as a blend of monomers, oligomers, and photo-initiators that conform into a hardened material via UV curing. When exposed to UV radiation as shown in Error! Reference source not found.[B], photo-initiator molecules undergo photolysis creating reactive radicals that react with monomers and oligomers forming chains of them. As these chains grow longer and longer, and create crosslinks, the photo-polymer resin changes from a liquid into a solid. This photo-polymerization process spans a few milliseconds.

The smallest feature size that can be printed by SLA 3D printers is limited by the cross section of the UV beam, or by the wavelength, used to irradiate the photo-polymer resin. In other words, if the irradiating wavelength is then the smallest resolvable feature must be equal of greater than Currently, most SLA 3D printers exhibit poor printing precision and accuracy because the prevalent use of UV Laser Diodes as a photo-polymer scriber with a cross section in the order of tens to hundreds of microns causes the photo-polymerization of clumps with dimensions of tens to hundreds of microns causing significant surface roughness. In practice, conventional optical lenses can resolve a beam spot to a diameter no smaller than λ22/D where is the wavelength and D is the diameter of the lens. This means That the spot size for a specific wavelength is dependent on increasing the diameter of the lens. This can impose a cost on optical systems as well as a physical limit to the level of miniaturization that can be achieved in their physical footprint. For nearly seven decades attempts have been made to produce a small spot of electromagnetic radiation using an engineered means of diffraction. In principle, there is no fundamental reason that this kind of “super-resolution” cannot be achieved. On this front, some attempts were mainly confined to academic approaches, which were experimentally demonstrated; however, these attempts either could not be manufactured or mass produced, or generated solutions that did not provide operational scalability.

It is well known to those of ordinary skill in the art that surfaces, and materials in general can be treated with photons in the ultraviolet (UV) segment of the electromagnetic radiation spectrum. Such irradiation may also include combinations other photons in the visible (Vis) and infrared (IR) segments of the electromagnetic spectrum, whose emission can be spontaneously occurring or engineered.

Spontaneous, stimulated, and/or engineered emission of UV radiation has been traditionally provided with a variety of discharge-based sources. Currently, mercury (Hg) vapor lamps play a dominant role as common discharge-based sources because phosphors can be integrated within their structure to emit visible electromagnetic radiation (light) for general lighting applications. For instance, compact fluorescent lamps (CFLs) though being phased out because of concerns linked to Hg pollution and disposal, are found in light fixtures around the world. When used without phosphors, Hg vapor lamps emit electromagnetic radiation in the UV-A, UV-B, and/or UV-C range; therefore—as part of a long-established custom since 1920's, these sources have been used for germicidal applications, and more recently for oxidation, curing, and general treatment purposes.

For the correct functionality of Hg vapor lamp, it is required that Hg is first vaporized and then ionized; UV photons are not emitted if this sequence is not completed. Warm-up times are therefore required, and during these times a given Hg vapor lamp will not provide an adequate UV irradiation level. There are three main categories of Hg vapor lamps: low pressure (LP), medium pressure (MP), or doped high pressure (HP). An ordinary LP Hg vapor lamp is characterized by relatively broader spectral emission centered at ˜254 nm, while a HP Hg vapor lamp exhibits a larger relative spectral emission centered at ˜365 nm. Independently of their classification, every kind of Hg vapor lamp exhibits a large distribution of smaller relative electromagnetic spectral emissions that span 185 nm to nearly 600 nm. While the spectral energy distribution of Hg mercury lamps can vary greatly from manufacturer to manufacturer, and from one kind of Hg vapor lamp to another, the energy spectral distribution is fixed for a given Hg vapor lamp. This implies that the single spectral emissions cannot be engineered to be enabled or disabled, red shift or blue shift; similarly, and most importantly the polarization of the emitted photons cannot be controlled either.

A less common kind of high pressure gas discharge is the excimer lamp, whose relatively narrower energy spectral emission (10 to 20 nm) is centered around a fixed wavelength in the range 126 to 352 nm; is broad (10 to 20 nm) and centered around a fixed wavelength in the range 126 to 351 nm. Similarly to other gas discharge lamps, the spectral emission of excimer lamps cannot be engineered to enable or disable desired wavelengths, red or blue shift, and control the polarization of the emitted photons.

Recent progress in excimer lamp technology has enabled microplasma UV sources, which have a much reduced foot print, in some cases comparable to solid state UV sources. Inside a microplasma UV source, stimulated xenon gas confined in microcavities produces UV radiation centered at 173 nm. Phosphors can be used to convert this wavelength in the UV-A, UV-B, or UV-C region of the electromagnetic spectrum including areas of interest in the range 173-220 nm, and at around the germicidal wavelength (260 nm). Microplasma UV sources are of significant commercial interest because their reduced footprint allows application where size constraint have prevented the use of conventional Hg vapor sources. However, similarly to other gas discharge lamps, the polarization of the emitted photons is not engineered.

Hg vapor or excimer lamps are characterized by a form factor, which is inflexible. Additionally, they typically require high power and high voltages; thus, they must use line voltage, and must be addressed as separate components that are not arbitrarily scalable. Because of the inflexible form factor of the Hg vapor, or excimer lamps, the architecture of the system that uses them is constrained. In a disinfection system for fluids, the typically tubular or linear Hg vapor or excimer lamps emit photons that pass through the fluid to be disinfected and are absorbed by another surface, or at best reflected once of twice before they are lost. This translates into a very inefficient use of photons, and a continuous need to generate and replace them. This also creates a scenario where there the radiation field is not uniform. In order compensate for losses and non-uniform radiation fields, increasingly high intensity Hg vapor or excimer lamps must be used.

During the last past two decades, solid state sources such as light emitting diodes (LEDs), Lase Diodes (LDs) have been engineered to emit UV radiation when a current in applied to them. UV LEDs and LDs are of great commercial interest. Because of their reduced footprint (typically 0.2 mm² to 1 mm²) they can enable commercial applications in disinfection, advanced oxidation, curing, polymerization, optical excitation where architecture constraints have impeded the use of conventional use Hg vapor lamps and excimer Lamps.

Most of solid state sources such as light emitting diodes (LEDs), Laser Diodes (LDs) generate UV radiation by recombining electrically charged carriers (electrons and holes) in the active region of a heterostructure typically made of an III-nitride semiconductor alloy that incorporates specific percentages of aluminum, gallium, and nitrogen.

Ternary III-nitride alloy

AlₓGa₍₁₋ₓ₎N

where “Al”, “Ga”, and “N” are the atomic symbols of elemental aluminum, gallium, and nitrogen, respectively; “x” is percent value. In this alloy the percent aluminum does not only determine the chemical composition but also the bandgap of the alloy, and the wavelength of the emitted photon.

Photon wavelength, λ (nm)

$$λ = \frac{\text{1,240}}{{E}_{g}}$$

where “E_{g}” is the bandgap energy expressed in electronvolt(eV). Based on peer-reviewed literature based values, for an alloy made of 100% aluminum, the bandgap value is 6.2 eV, and 3.4 eV for an alloy containing 0% aluminum, which respectively yields emission of photons with a wavelength of 200 nm, and 365 nm, respectively. By varying the percent of Aluminum between 0% and 100%, solid-state devices such as LEDs can be engineered to generate emission of UV-A, UV-B, and UV-C radiation. While the photon emission can be engineered, the polarization of the emitted photons is not engineered.

Solid-state sources such as UV LEDs and UV LDs, and microplasma UV sources are used to perform the same functions as Hg vapor lamps. In addition they are environmentally friendly because of the absence of Hg; however, differently from Hg vapor lamps, they enable zero-emission limitations because their on-off operation and their UV emission is pseudo-instantaneous and limited to only a few nanoseconds when supported by adequate electronic drivers.

Additionally, the transmission of UV photons is also affected by the transparency of the medium, a phenomenon that is generally described by the Beer-Lambert Law. According to this known law, the attenuation of radiation traveling through a medium is related to the properties of the medium itself, and also directly proportional to the concentration(s) of the attenuating species. such as particles, pollutants, and compounds that are present in the medium.

Beer-Lambert Law

$$T = \frac{{φ}_{e}^{t}}{{φ}_{e}^{i}} = {e}^{- τ} = {10}^{- A}$$

where “T” is the Transmittance of the medium, Φₑ^{†} is the radiant flux transmitted through the medium, Φₑⁱ is the radiant flux received by the medium, τ is the optical depth of the medium, A is the absorbance of the medium.

N attenuating species in the medium

T=e⁻Σᵢ₌₁^{N}τ₁∫₀^{l}nᵢ(z)dz=10⁻Σᵢ₌₁^{N}ξ₁∫₀^{l}cᵢ(z)dz

where “τ” is the attenuation cross section of the attenuating species “i” in the medium, “nᵢ” is the number density of the attenuating species “i” in the medium, “ξ” in the absorptivity of the attenuating species “i” in the medium, “cᵢ” in the amount concentration of the attenuating species “i” in the medium, and “l” is the path length of the radiation through the medium.

Another naturally occurring phenomenon that hinders the treatment of surfaces and materials with UV photons is the Rayleigh scattering, which is the dominant elastic scattering of electromagnetics radiation by particles of organic and inorganic material, that are at least 10X smaller than the wavelength of the radiation. This phenomenon can occurs when electromagnetic radiation travels trough solids, liquids, and gases that are transparent to the radiation itself. This phenomenon is caused by the electric polarizability of matter organized into a “particle” much smaller than the irradiating wavelength. The oscillating electric field of an electromagnetic wave acts on the charges within the “particle” causing them to resonate with a similar frequency. In this case the “particle” turns into a radiating dipole that scatters electromagnetic radiation.

Several impediments that stem from the Beer-Lambert Law, and the Rayleigh scattering seriously hinder the use of UV radiation for treatment of fluids.

It is well known to those of ordinary skill in the art that the field of physics offers different definitions of electromagnetics radiation.

In classical electrodynamics, electromagnetic radiation is defined with the concept of electromagnetic waves, which are a oscillations of electric and magnetic fields, synchronized and perpendicular to each other and perpendicular to the direction of the wave propagation, forming a transverse wave. In other words, if the direction of the wave propagation in the x-direction in the x-plane of a 3D Cartesian axis system, then the oscillations of the electric and magnetic fields occur in the y-z plane.

In quantum theory of electromagnetism, electromagnetic waves consist of elementary, massless particles called photons, which are responsible for all electromagnetic interaction. Energy is carried by photons, and the energy of each single photon is quantized and expressed by Planck's equation.

Planck's Equation

E=hv

where “h” is Planck's Constant, and “v” is the frequency of the photon.

The wavelength of the photon generated in the active region of a semiconductor-based heterostructure can be linked to Plank's equation.

Photon wavelength, λ (nm) and Planck's Equation

$$E = hv = h \frac{c}{λ} ∴ λ ( nm ) = h \frac{c}{E} = \frac{( 4.136 \times {10}^{- 15} eV s ) ( 2.998 \times {10}^{8} m {s}^{- 1} )}{E} = \frac{\text{1,240}}{{E}_{g}}$$

where “E_{g}” is the bandgap energy of the active region of a semiconductor-based heterostructure of the expressed in electronvolt (eV).

It is well known to those of ordinary skills that electromagnetic radiation carries energy. Nonetheless it is less widely known that electromagnetic radiation also carries momentum, which is a characteristics property of an object in translational motion, or more precisely the movement that changes the physical position of an object, as opposed to rotational motion. Most can relate to the Newtonian definition of momentum as the product of the mass of the velocity of an object in translational motion, which is less intuitive when applied photons as massless particles; nonetheless, practical evidence that electromagnetic radiation carries momentum is found in the physical phenomenon known as “radiation pressure”, in which a flux of photons transfer their momentum to an absorbing or scattering object and exert pressure on it.

The magnitude of the pressure exerted on a body by radiation, when the momentum carried by the former is transferred by the radiation, is relatively speaking small and therefore difficult to be observed by human beings without the aid of instrumentation. But it the overall scheme of things, radiation pressure can have non-negligible effects. If the pressure exerted by radiation emanated by the Sun in our solar system were not considered (determined to be 1,361 Wm⁻² at 1 AU, i.e. the distance from the Sun to Earth.), the trajectory of spacecraft in our solar system would have been affected with significant theoretical vs. experimental deviations.

Experimental proof that electromagnetic radiation carries momentum was obtain during the years 1901-1903 by Russian physicist Pyotr Lebedev, and American physicists Earnest Fox Nichols and Gordon Ferrie Hull, following the assertion that electromagnetic radiation carries momentum published by Scottish scientist James Clerk Maxwell in 1865. However, it was the German astronomer Johannes Kepler that first reported in 1619, that the tail of a comet always points away from Sun, intuiting that sunlight was exerting some force on the comet tail.

The concept that electromagnetic radiation carries momentum is very important because the implication is that momentum is a conserved quantity. In other words, the momentum carried by electromagnetic radiation remains unchanged until acted upon by an external system, or transferred or absorbed by another body, or matter in general. The exchange of momentum with matter is a phenomenon that is not widely known. Thought is has been exploited to generate optical tweezers, the interaction of momentum carried by UV photons with matter is not widely known because both UV photon sources and UV compatible materials have been historically scarce.

As it travels in space, electromagnetic radiation can also rotate around its own axis of propagation. This rotation can assume two distinct forms, which are associated with two distinct forms of angular moment.

One form of rotation is characterized by the circular polarization of the electromagnetic magnetic wave, which occurs when the electric field vector rotates at a constant rate around the propagation axis (circular polarization). A circularly polarized electromagnetic wave can be in one of two possible states, namely right or left circular polarization. From quantum physics point of view, the circular polarization is linked to the spin of a phonon, which too can be found in one of two possible states, namely right or left spin.

The other known form of rotation is characterized by the shape of the wavefront, which is the distribution is space of propagation points (surface) characterized by the same phase.

The form or rotation involving the electric field vector of an electromagnetic wave (or photon spin) is associated with a kind of angular momentum known as Spin Angular Momentum (SAM); the form or rotation involving the shape of the wavefront is associated with a kind of angular momentum known as Orbital Angular Momentum (OAM).

Spin Angular Momentum (SAM) is associated with the circular polarization of the electromagnetic magnetic wave, which occurs when the electric field vector rotates at a constant rate around the propagation axis. Depending on the field rotation and the commonly accepted conventions, the circular polarization can be “left” or “right” as illustrated in FIG. 3. From a quantum physics point of view, electromagnetic radiation carries SAM when photons carry a spin angular momentum of ±h, where h is the reduced Plank constant, and the + is the sign associated with left circular polarization, and the − is the sign associated with right circular polarization. In other words the circular polarization is linked to the spin of a phonon, which too can be found in one of two possible states, namely right or left spin.

Orbital Angular Momentum (OAM) is associated on the field spatial distribution of the electric field, not with its polarization. It is categorized as external or internal OAM. The external OAM is origin dependent angular momentum that results from the cross product of special location of the center of the beam of electromagnetic wave and its total linear momentum. The internal OAM is associated with an origin-independent angular moment with a helical mode. Helical modes of electromagnetic fields are characterized by wavefront that is shaped like a helix, with an optical vortex at the center of the electromagnetic radiation beam. In this case of non-cylindrical symmetry wave propagating along the z-axis, the OAM can be expressed as

L_{z}=mh

where h is the reduced Plank constant, α m is integer called the topological charge. If m≥2 then the wavefront is composed of |m| distinct yet intertwined helixes with step length equal to |m|λ, where λ is the wavelength of the electromagnetic radiation wave, and direction determined by the sign of |m|.lf m=1, then the wavefront is composed by a single helical surface with step length equal to λ. If m=0, then mode if not helical, and wavefront is composed by a simple flat surface.

It is less commonly known that angular momentum carried by electromagnetic radiation can be transferred on to matter. When electromagnetic radiation carrying a non-zero angular momentum (SAM or OAM) impinges on the axis of an absorbing particle, the particle will absorb the angular momentum; this causes the absorbing particle to acquire a rotational motion. If the absorbing particle is impinged off-axis by different photons carrying different angular momenta, then the particle will be subjected to a combination of different rotational motions. SAM will induce rotational motion around the axis of an absorbing particle (particle spinning). OAM will induce a revolution of the absorbing particle around the OAM axis of the electromagnetic radiation; the form or rotation involving the shape of the wavefront is associated with a kind of angular momentum known as Orbital Angular Momentum (OAM).

Circular polarization of electromagnetic radiation, which carries spin angular momentum (SAM) is commonly achieved by means of quarter wave plates, which are planar devices made of birefringent materials. These birefringent materials are crystalline materials that exhibit an index of refraction dependent of the crystallographic direction. Birefringent materials are characterized by two possible optical paths corresponding to two different indexes of refraction, which basically describe the speed of propagation of electromagnetic radiation in a given medium. Within a birefringent material, electromagnetic radiation can propagate with two distinct possible speeds depending on the direction of electromagnetic radiation. A quarter wave plate is designed so that electromagnetic radiation propagating in the direction with the larger index of refraction is retarded by 90° in phase with respect to the phase of the electromagnetic radiation propagating in the direction with the smaller index of refraction.

There exist design algorithms for obtaining super-resolution with coherent, incoherent, or a mixture of coherent or incoherent radiation near-UV and/or UV radiation.

Traditionally, super-resolution is achieved with lenses, which are designed numerically by modifying a pattern of concentric rings until the target design is obtained. Though this approach can potentially be extended to incorporate additional design criteria, it does usually not allow one to design a specified trade-off between resolution and power efficiency, nor the location of the undesired side lobes in the super-resolving focal plane.

There exist design algorithms for obtaining super-resolution with coherent, incoherent, or a mixture of coherent or incoherent radiation near-UV and/or UV radiation.

The Prior Discrete Fourier Transformation (PDFT) algorithm is an_example of design algorithm for obtaining super-resolution with coherent near-UV and/or UV radiation.

The PDFT algorithm was originally conceived as a super-resolution imaging technique. The mechanism of the PDFT algorithm may be summarized as follows. At a finite set of arbitrary points, the signal value is expressed as the superposition of a set of linear independent functions, which express prior knowledge we have about the signal synthesis problem. For super-resolution filters this may be the bandwidth of the signal and the functions are shifted Sinc functions. The solution of the PDFT provides the minimum norm transmission function compatible with the specified signal values.

Generally, the PDFT solution will be real valued or complex valued and an addition-encoding step is necessary to turn the PDFT solution into the phase-only transmission function of a standard diffractive optical element.

Nonlinear design algorithms have also been used to design super-resolution filters. These algorithms optimize the zone width of domains of constant phase inside the DOE aperture, either matching a finite set of signal samples, or optimizing additional components of a more complex cost function.

More recently, super-resolution elements were demonstrated based on the concept of super-oscillations. The design mechanism is very similar to the PDFT, but done in the z-transform domain, which unnecessarily limits the specified signal points to zero crossings of the output spot.

There are several methods to generate orbital angular momentum (OAM), including holograms (pitch-fork, fork-like, or computer generated spatial light modulators), Q-plates, Cylindrical Mode Converters, and dielectric metasurfaces.

What is still needed in the art, however, is a system that can that generate UV photons with engineered SAM, OAM, and/or combination of both to achieve optimized angular momentum transfer onto matter, and to treat organic and inorganic substances. Also, in order to increase precision, accuracy, and resolutions of SLA 3D printers, it is still needed a system that allows to reduce the UV radiation beam size so that is can be smaller than the emitting source, and/or smaller that its wavelength.

### BRIEF SUMMARY OF THE INVENTION

In various exemplary embodiments, the present invention provides a system for transferring a super-resolved beam of near-UV and/or UV photons (beam with subwavelength beam diameter and/or feature), of near-UV and/or UV photons with engineered angular momentum on to matter, and treat organic and inorganic substances comprising a coherent or incoherent source of near-UV and/or UV photons, and one or more angular momentum generators configured to deliver UV photons with optimized spin angular momentum (SAM), orbital angular momentum OAM, and/or a SAM/OAM combination to target organic or inorganic substance, wherein the angular momentum generators are scalable such that they can be fabricated as a stand alone structure, as a structure fabricated on the package of the near-UV and/or UV photon source, or as an integral part of the of near-UV and/or UV photon source.

In one exemplary embodiment, the present invention provides a system for 3D printing utilizing non-UV, near-UV, and/or UV photons with or without engineered angular momentum, which may be organized as shaped flux or flux shaping structures of non-UV photons, near-UV photons, and/or UV photons, the system comprising: one or more of a coherent source, a partially-coherent source, and an incoherent source of one or more of non-UV photons, near-UV photons, and UV photons; and one or more flux shaping structures or angular momentum generators, with or without flux shaping, configured to impart the one or more of the non-UV photons, the near-UV photons, and the UV photons with one or more of spin angular momentum (SAM) and orbital angular momentum (OAM); wherein the one or more flux shaping structures or angular momentum generators, with or without flux shaping, are one or more of fabricated as stand-alone structures, fabricated on a package of the one or more of the coherent source, the partially-coherent source, and the incoherent source, and fabricated as an integral part of the one or more of the coherent source, the partially-coherent source, and the incoherent source. The system further comprising means for obtaining one or more of super-resolution and flux-shaped non-UV photons, near-UV photons, and UV photons one or more of fabricated as a stand-alone structure, fabricated on the package of the one or more of the coherent source, the partially-coherent source, and the incoherent source, and fabricated as an integral part of the one or more of the coherent source, the partially-coherent source, and the incoherent source. The one or more angular momentum generators or flux shaping structures comprise one or more Spiral Phase Plates made of a non-UV, near-UV, and/or UV transparent material operable for imparting OAM. The one or more angular momentum generators or flux shaping structures comprise one or more computer generated diffraction gratings with groove bifurcation comprising one of a fork hologram, a pitchfork hologram, and a fork-like hologram operable for imparting OAM by passing a flux of electromagnetic radiation having incident circular Lauerre-Gaussian through the computer generated diffraction grating. The one or more computer generated diffraction gratings comprise one or more phase filters exhibiting super-resolution or flux shaping capabilities. The one or more angular momentum generators or flux shaping structures comprise one or more Q-plates operable for imparting one or more of SAM and OAM. The one or more Q-plates are implemented dynamically using one or more of liquid crystals, polymers, and subwavelength gratings. The one or more angular momentum generators or flux shaping structures comprise one or more thin single domain magnetic needles approximating a magnetic monopole used to generate an optical vortex operable for imparting OAM. The one or more of the coherent source, the partially-coherent source, and the incoherent source comprises one of a non-UV, near-UV, and/or UV Laser, a non-UV, near-UV, and/or UV Light Emitting Diode, and a non-UV, near-UV, and/or UV emitting plasma discharge lamp. The one or more angular momentum generators or flux shaping structures comprise a Prior Discrete Fourier Transformation (PDFT) phase filter that exhibits super-resolving and/or flux shaping capabilities configured to deliver a super-resolved and/or flux shaped beam configured to be coupled to an optical fiber. The 3D printing comprises one of Right-Side-Up SLA 3D printing, and Inverted SLA 3D printing, and a Non-SLA 3D printing that uses a photochemical reaction to print an object.

In another exemplary embodiment, the present invention provides a system for 3D printing utilizing non-UV, near-UV, and/or UV photons with engineered angular momentum or shaped flux, the system comprising: one of a coherent source, a partially-coherent source, and an incoherent source of one or more of non-UV photons, near-UV photons, and UV photons; means for obtaining one or more of super-resolved and flux-shaped non-UV photons, near-UV photons, and super-resolved UV photons; and one or more angular momentum generators or flux shaping structures configured to impart the one or more of the non-UV photons, the near-UV photons and the UV photons with one or more of spin angular momentum (SAM) and orbital angular momentum (OAM); wherein the means for obtaining and the angular momentum generators or flux shaping structures are one or more of fabricated as stand-alone structures, fabricated on a package of the one of the coherent source, the partially-coherent source, and the incoherent source, and fabricated as an integral part of the one of the coherent source, the partially-coherent source, and the incoherent source. The one or more angular momentum generators or flux shaping structures comprise one or more Spiral Phase Plates made of a non-UV, near-UV, and/or UV transparent material operable for imparting OAM. The one or more angular momentum generators or flux shaping structures comprise one or more computer generated diffraction gratings with groove bifurcation comprising one of a fork hologram, a pitchfork hologram, and a fork-like hologram operable for imparting OAM by passing a flux of electromagnetic radiation having incident circular Lauerre-Gaussian through the computer generated diffraction grating. The one or more computer generated diffraction gratings comprise one or more phase filters exhibiting super-resolution or flux-shaping capabilities. The one or more angular momentum generators or flux shaping structures comprise one or more Q-plates operable for imparting one or more of SAM and OAM. The one or more Q-plates are implemented dynamically using one or more of liquid crystals, polymers, and subwavelength gratings. The one or more angular momentum generators or flux shaping structures comprise one or more thin single domain magnetic needles approximating a magnetic monopole used to generate an optical vortex operable for imparting OAM. The one of the coherent source, the partially-coherent source, and the incoherent source comprises one of a non-UV, near-UV, and/or UV Laser, a non-UV, near-UV, and/or UV Light Emitting Diode, and a non-UV, near-UV and/or UV emitting plasma discharge lamp. The one or more angular momentum generators comprise a Prior Discrete Fourier Transformation (PDFT) phase filter that exhibits super-resolving capabilities configured to deliver a super-resolved beam configured to be coupled to an optical fiber. The 3D printing comprises one of Right-Side-Up SLA 3D printing, and Inverted SLA 3D printing, and a Non-SLA 3D printing that uses a photochemical reaction to print an object. The means for obtaining the one or more of the super-resolved or flux-shaped non-UV, near-UV, and/or UV photons comprises one or more of (a) lenses designed numerically by modifying a pattern of concentric rings until a target design is obtained, (b) lenses designed using a Prior Discrete Fourier Transformation (PDFT) algorithm, (c) lenses designed using a nonlinear design algorithm that optimizes a zone width of domains of constant phase inside an aperture, either matching a finite set of signal samples or optimizing other components, and (d) super-resolution elements based on super-oscillations. The non-UV photons, the near-UV photons, and/or the UV photons are used for treatment of organic or inorganic substances and/or impurities resulting in dimerization or alteration of nucleic acids and/or proteins, accelerated or decelerated polymerization rates, altered polymerization characteristics, and/or lowered activation energy of a chemical reaction, nuclear reaction, or other physical phenomena.

### BRIEF DESCRIPTION OF THE DRAWINGS

The present invention is illustrated and described herein with reference to the various drawings, in which:

FIG. 1 is a schematic diagram illustrating two of the most recurrent configurations for a SLA 3D Printer: [A] Inverted SLA System, and [B] Right-Side Up SLA System;

FIG. 2 is a schematic diagram illustrating a conceptualization of the photo-polymerization process—[A] Untreated photo-polymer; [B] Photopolymer treated with UV electromagnetic radiation; [B][1] Untreated photo-polymer depicted as a blend of monomers, oligomers, and photo-initiators; [B][2] When exposed to UV radiation, photo-initiator molecules undergo photolysis creating reactive radicals;

[B][3] Reactive radicals react with monomers and oligomers forming chains of them; As these chains grow longer and longer, and create crosslinks, the photo-polymer resin changes from a liquid into a solid;

FIG. 3 is a schematic diagram illustrating a conceptualized circular polarization of an electromagnetic wave—the rotation of the electric field component of the electromagnetic wave around the propagation axis is shown: [A] right circularly polarized, and [B] left circularly polarized;

FIG. 4 is a schematic diagram illustrating a conceptualized wavefront of an electromagnetic wave carrying Orbital Angular Momentum (OAM)—in this specific case, the illustration shows OAM with topological charge, m=±1: [A] m=−1[B] m=+1.

FIG. 5 is a schematic diagram illustrating a conceptualized exchange of spin and angular momentum with matter; [A] Spin angular momentum transfer on to an absorbing particle, which acquires a rotational motion; [B] Orbital angular momentum transfer on to an absorbing particle, which will revolve around the OAM axis of the beam of electromagnetic radiation;

FIG. 6 is a schematic diagram illustrating one exemplary embodiment of the system and method for enhanced treating of matter with engineered angular momentum UV photons;

FIG. 7 is a schematic diagram illustrating another exemplary embodiment of the system and method for enhanced treating of matter with engineered angular momentum of near-UV and/or UV photons:

FIG. 8 is a schematic diagram illustrating another exemplary embodiment of the system and method for enhanced treating of matter with engineered angular momentum of near-UV and/or UV photons;

FIG. 9 is a schematic diagram illustrating another exemplary embodiment of the system and method for enhanced treating of matter with engineered angular momentum of near-UV and/or UV photons;

FIG. 10 is a schematic diagram illustrating the effect of the invention of using UV photons with engineered angular momentum to treat matter;

FIG. 11 is a schematic diagram illustrating the domain of application of the current innovation;

FIG. 12 is a schematic diagram illustrating the use of the innovation within a SLA 3D printer;

FIG. 13 is a schematic diagram illustrating the use of the innovation within a SLA 3D printer;

FIG. 14 is a schematic diagram illustrating the use of the innovation within a SLA 3D printer;

FIG. 15 is a schematic diagram illustrating the use of the innovation within a SLA 3D printer.

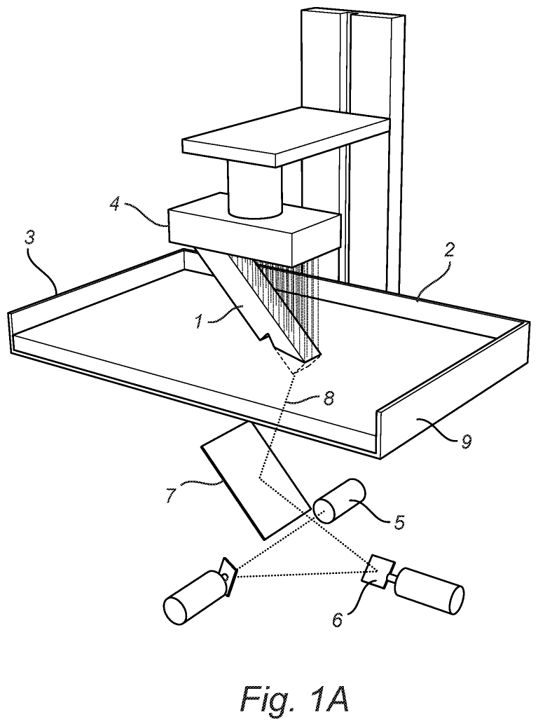

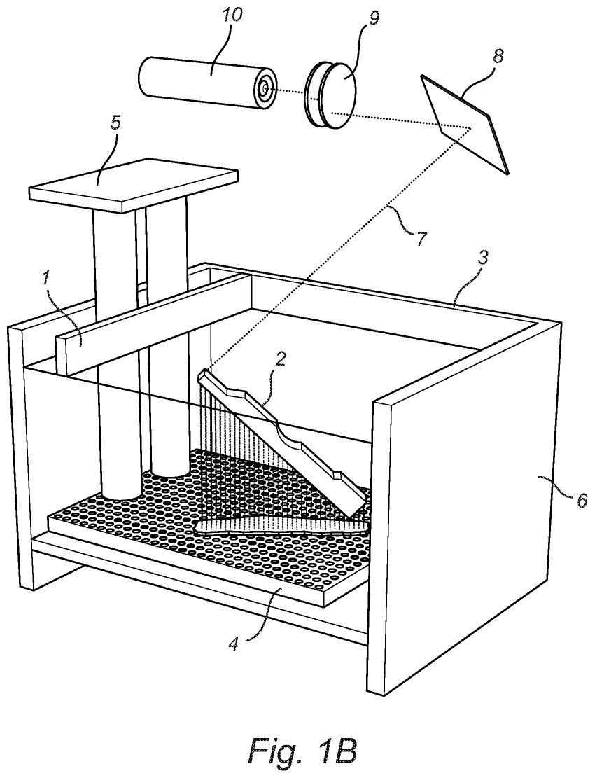

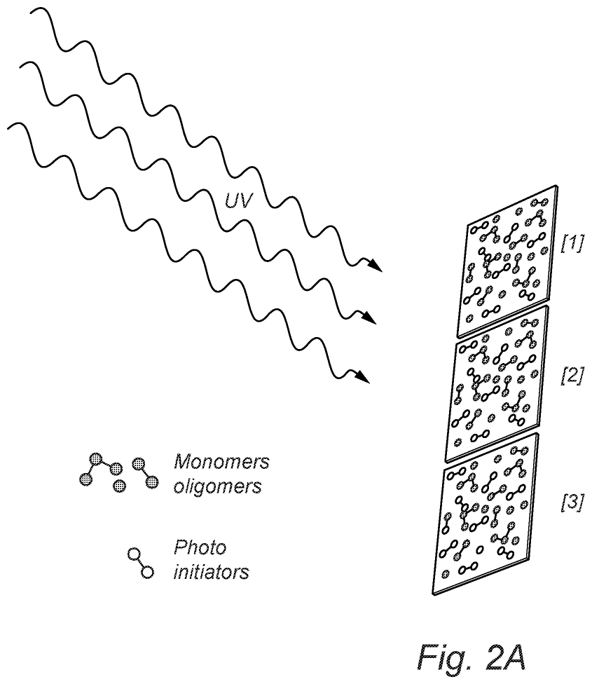

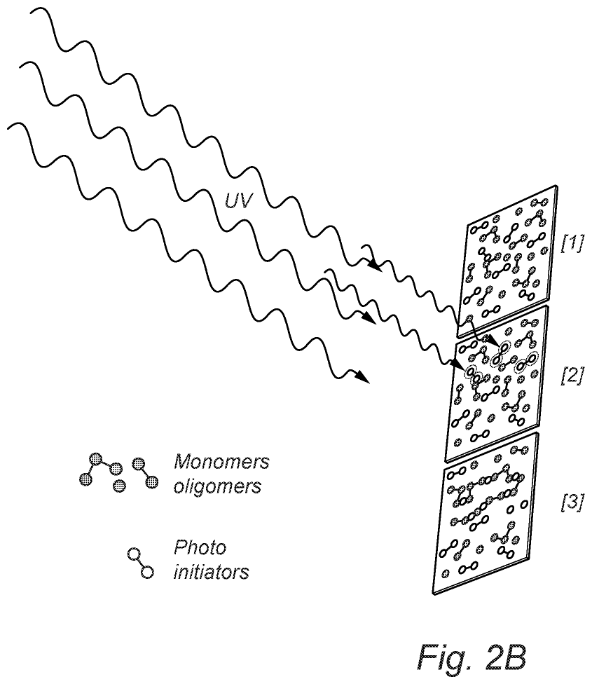

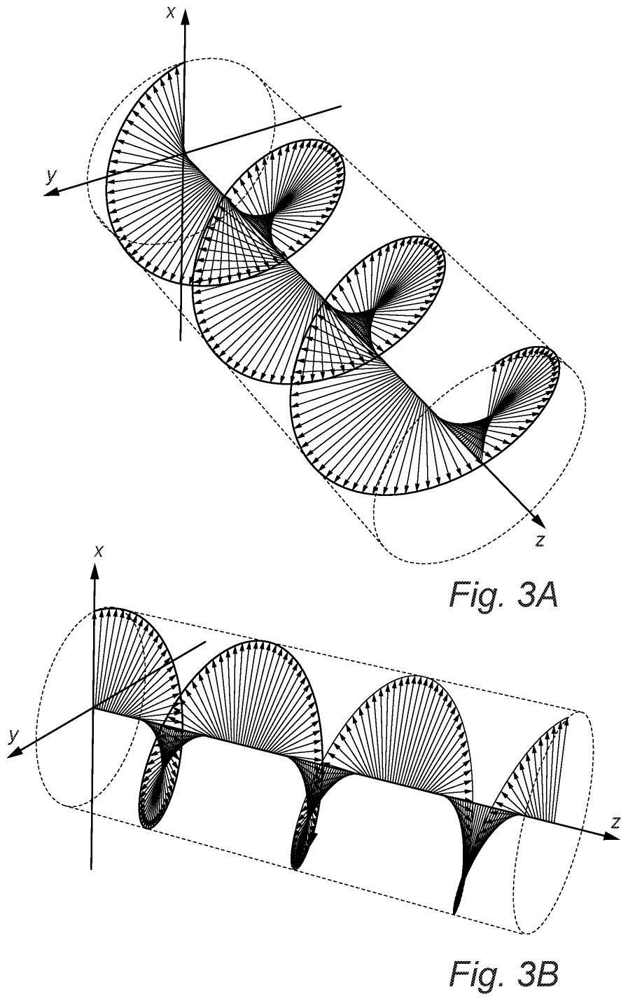

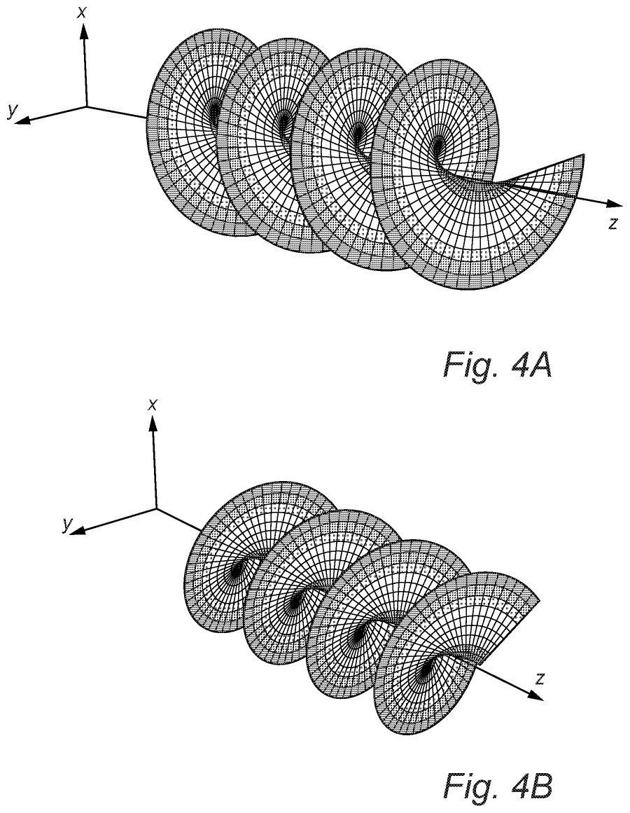

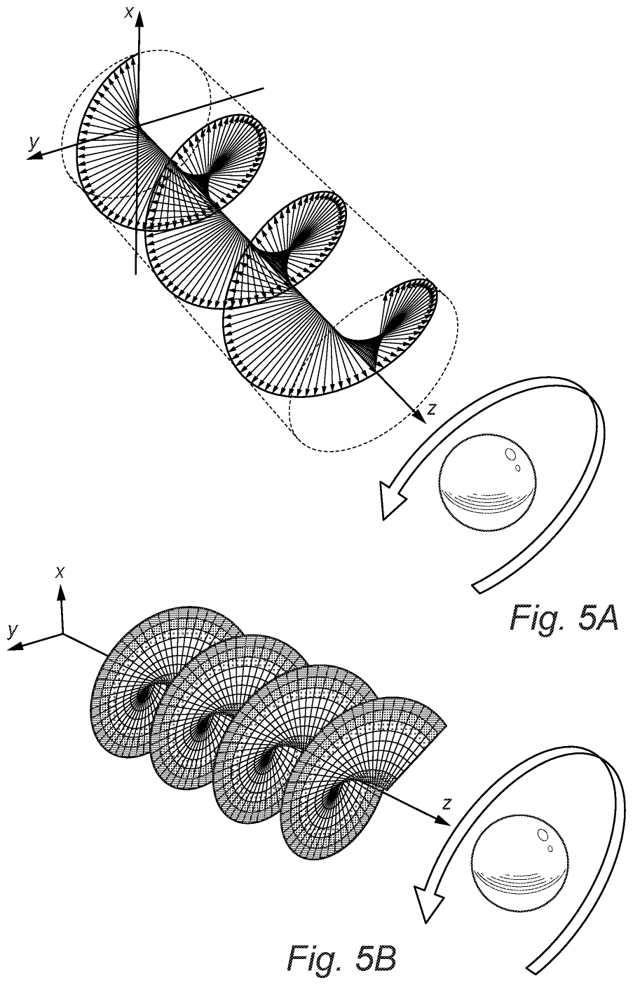

### DETAILED DESCRIPTION OF THE INVENTION

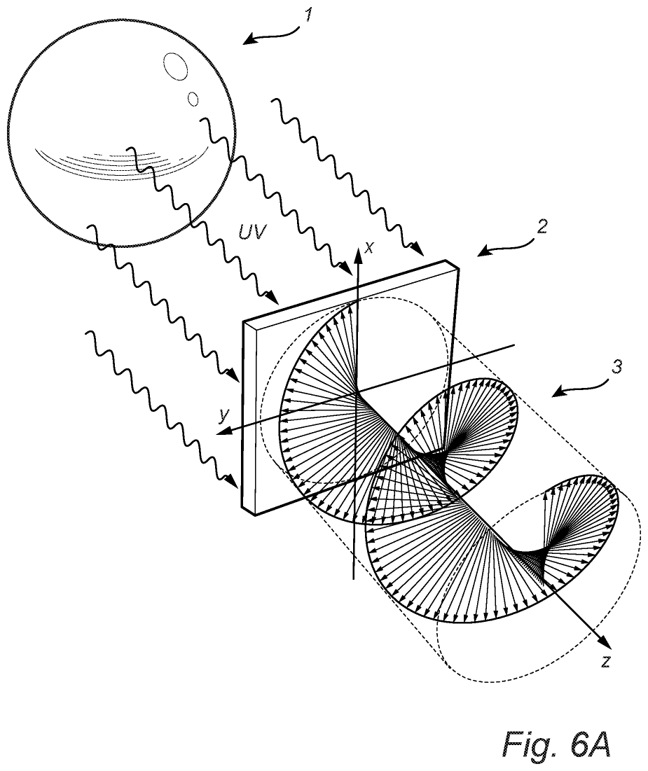

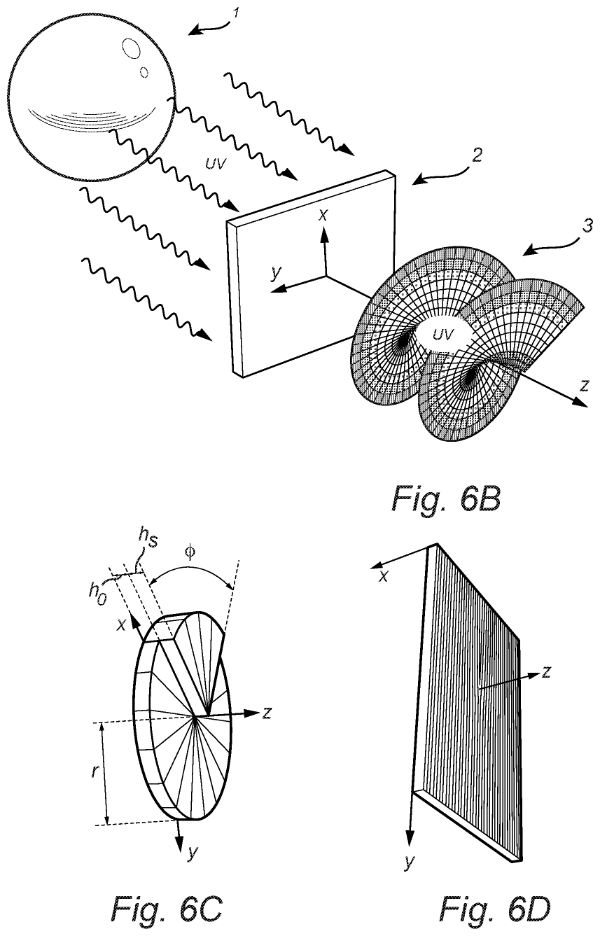

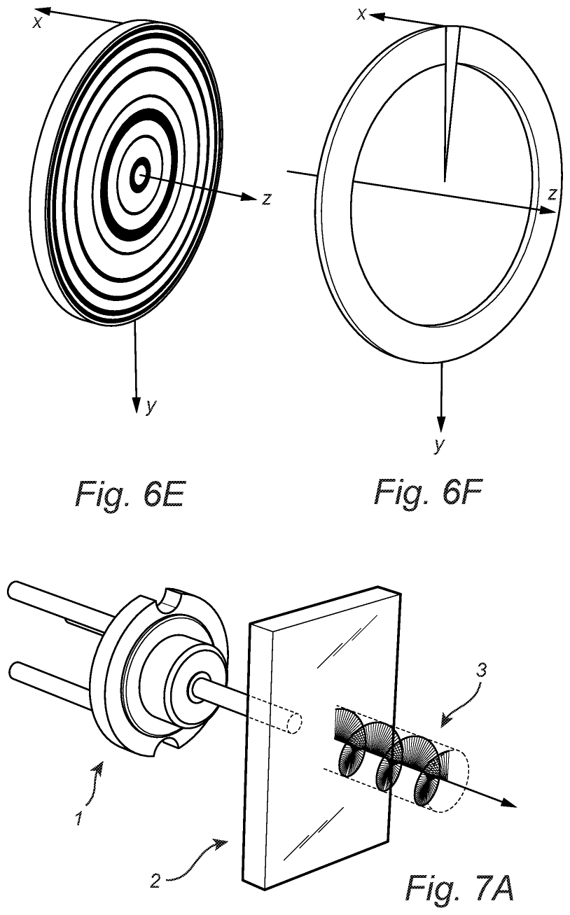

Referring now specifically to FIG. 6, one representation of the invention is an apparatus [A], [B] comprising a source of UV photons [1], one or more stand alone angular momentum generators [2] configured to deliver UV photons with optimized spin angular momentum (SAM), org orbital angular momentum (OAM), and/or a SAM/OAM [3] combination to target organic or inorganic substance and/or impurity. The angular momentum generator can have different forms [a], [b], [c], and [d].

Referring now specifically to FIG. 6 [2a] UV photons can acquire optimized OAM with a Spiral Phase Plate made of UV transparent material with refractive index n, having an inhomogeneous thickness, h proportional to the azimuthal angle Φ

$$h = {h}_{s} \frac{φ}{2 π} + {h}_{0}$$

where hₛ is the step height, and h₀ is the base height. When a beam of electromagnetic radiation (Gaussian) with plane phase distribution passes through this OAM generator, an optical vortex charge q is imprinted according to

$$q = \frac{{h}_{s} ( n - {n}_{0} )}{λ}$$

This means that the output beam of electromagnetic radiation will carry OAM per photon equal to qh, where h is the Reduced Planck's constant. For a given electromagnetics wavelength λ in the UV range of the electromagnetic spectrum, then the vortex charge q can be engineered by controlling the optical step hₛ.

Referring now specifically to FIG. 6 [2b] UV photons can acquire optimized OAM by passing flux of electromagnetic radiation having incident circular Lauerre-Gaussian through a computer generated diffraction grating with groove bifurcation known as fork holograms, pitchfork holograms, or fork-like holograms. If as single groove divides into μ+1 branches then the n-order diffracted beam of electromagnetic radiation acquires the optical vortex (photons carrying OAM) with topological charge

l=μn

[2b] shows fork hologram with a single groove that divides into 1 branch, therefore μ=1. For a given electromagnetic wavelength λ in the UV range of the electromagnetic spectrum, then the topological vortex charge I can be engineered by controlling the number of branches. For operation for a given electromagnetic wavelength λ in the UV range, the diffraction grating needs to be fabricated with features equal of smaller than said wavelength λ.

Computer generated holograms that function as angular momentum generators can be designed and fabricated as phase filters that also exhibit super-resolving capabilities. Super-resolution diffracting elements are designed numerally by modifying a pattern of concentric rings similar to those illustrated in [2c]. Super-resolved Phase filters that function as angular momentum generators can be based on the so-called use a design methods based on the so-called “Prior Discrete Fourier Transformation” (PDFT). For operation for a given electromagnetic wavelength A in the UV range, concentric ring patterns, and PDFT patterns must be fabricated with features equal of smaller than said wavelength λ.

[2c] shows a Q-plate used as SAM/OAM angular momentum generator. Similarly to a Spiral Phase Plate [2a], a Q-plate influences electromagnetic radiation by making it interact with matter that is both optically inhomogeneous and anisotropic. The design of a Q-plate can be implemented dynamically using liquid crystals, and polymers, or subwavelength gratings. For operation for a given electromagnetic wavelength λ in the UV range, the patterns created with liquid crystals or polymers, and the features of the gratings must be equal of smaller than said wavelength λ.

[2d] shows a thin single domain magnetic needle approximating a magnetic monopole used to generate an optical vortex (OAM carrying photons) angular momentum generator. A beam of electromagnetic radiation is passed through a through a round aperture upon which a thin-tip magnetic rod is secured. OAM tuning is controlled by the magnetization of the single domain magnetic needle.

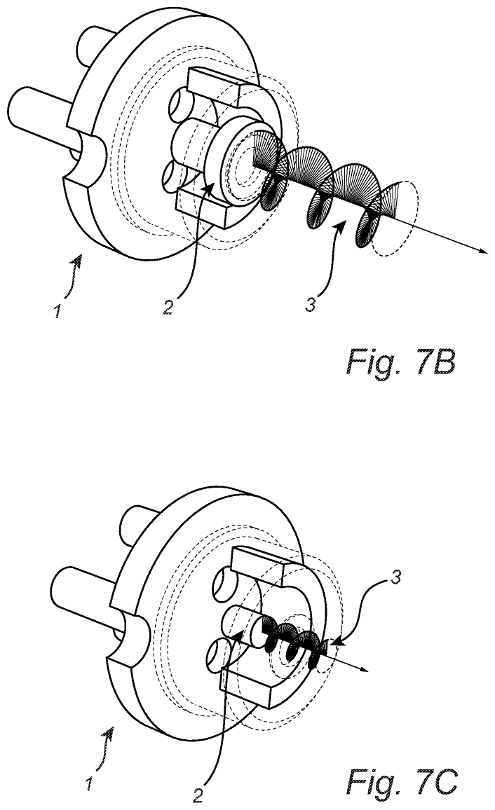

Referring now specifically to FIG. 7, one representation of the invention is an apparatus [A], [B], and [C] comprising a source of UV photons such as, but not limited to a UV Laser, a UV Light Emitting Diode, or a UV emitting plasma discharge lamps [1], one or more stand alone angular momentum generators [2] configured to deliver UV photons with optimized spin angular momentum (SAM), org orbital angular momentum (OAM), and/or a SAM/OAM [3] combination to target organic or inorganic substance and/or impurity. In this particular incarnation, the idea is to have a design for an optimized angular generator such as a Spiral Phase Plate, a hologram, a Q-plate, or a single domain magnetic needle approximating a magnetic monopole that can be fabricated and scaled using Very large Scale Integration (VLSI) fabrication techniques so that the device can be fabricated—as an array or not- onto the surface of a freestanding UV transparent medium, FIG. 7 [A][2], or onto the surface of a UV transparent window (an aperture) such as the UV transparent window of a packaged UV Laser Diode, FIG. 7 [B][2]. Since hologram features must be equal or smaller then the UV wavelength (400 nm or smaller), then VLSI fabrication techniques can be used to integrate an optimized angular generator such as a Spiral Phase Plate, a hologram, a Q-plate, or a single domain magnetic needle approximating a magnetic monopole onto the surface of a solid state die (Laser Diode, Light Emitting Diode, Microplasma Discharge Bulb” as shown in FIG. 7 [C][2].

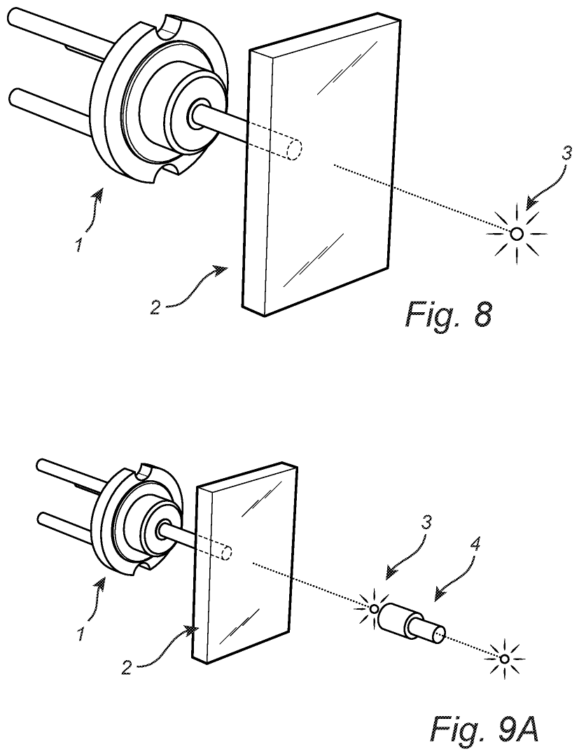

Referring now specifically to FIG. 8, one representation of the invention is an apparatus comprising a source of UV photons such as, but not limited to a UV Laser, a UV Light Emitting Diode, or a UV emitting plasma discharge lamps [1], an angular momentum generator that is also a PDFT phase filter or similar phase/diffractive filter that exhibits super-resolving capabilities [2] configured to deliver a super-resolved beam of UV photons with optimized spin angular momentum (SAM), org orbital angular momentum (OAM), and/or a SAM/OAM combination [3] that can be efficiently coupled to fiber optics [4] to target organic or inorganic substance and/or impurity. In this particular incarnation PDFT patterns must be fabricated with features equal of smaller than said wavelength λ.

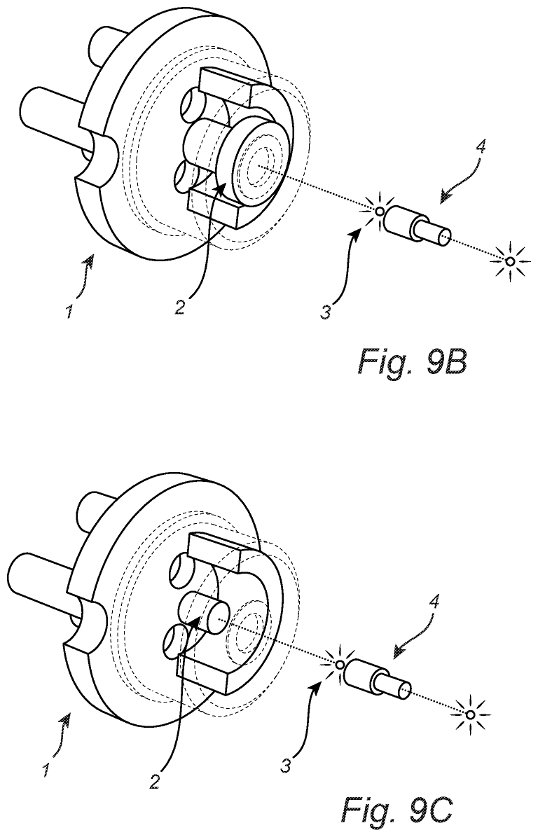

Referring now specifically to FIG. 9, one representation of the invention is an apparatus comprising a source of UV photons such as, but not limited to a UV Laser, a UV Light Emitting Diode, or a UV emitting plasma discharge lamps [1], an angular momentum generator that is also a PDFT phase filter or phase/diffractive filter that exhibits super-resolving capabilities [2] configured to deliver a super-resolved beam of UV photons with optimized spin angular momentum (SAM), org orbital angular momentum (OAM), and/or a SAM/OAM combination [3] that can be efficiently coupled to fiber optics [4] to target organic or inorganic substance and/or impurity. In this particular incarnation, the idea is to have a design for an angular momentum generator that is also a PDFT phase filter that exhibits super-resolving capabilities that can be fabricated and scaled using Very large Scale Integration (VLSI) fabrication techniques so that the device can be fabricated—as an array or not—onto the surface of a freestanding UV transparent medium, FIG. 9 [A][2], or onto the surface of a UV transparent window (an aperture) such as the UV transparent window of a packaged UV Laser Diode, FIG. 9 [B][2]. Since the features of the momentum generator/PDFT super-resolving phase filter must be equal or smaller then the UV wavelength (400 nm or smaller), then VLSI fabrication techniques can be used to integrate it onto the surface of a solid state die (Laser Diode, Light Emitting Diode, Microplasma Discharge Bulb” as shown in FIG. 9 [C][2].

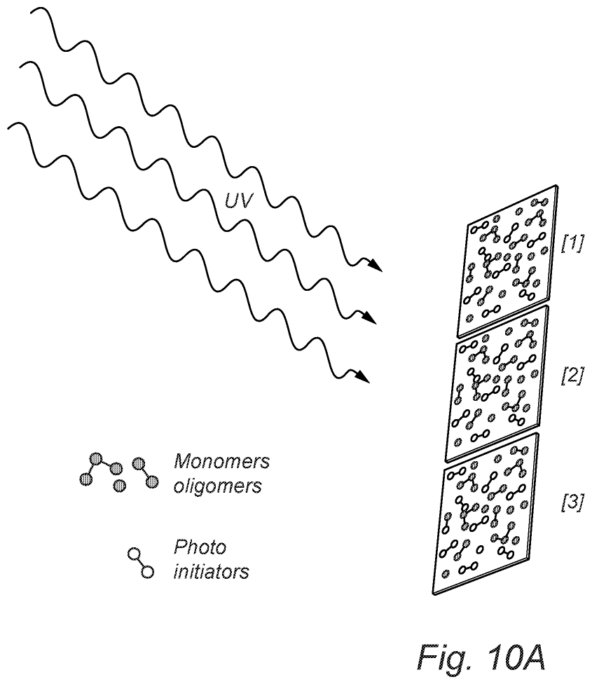

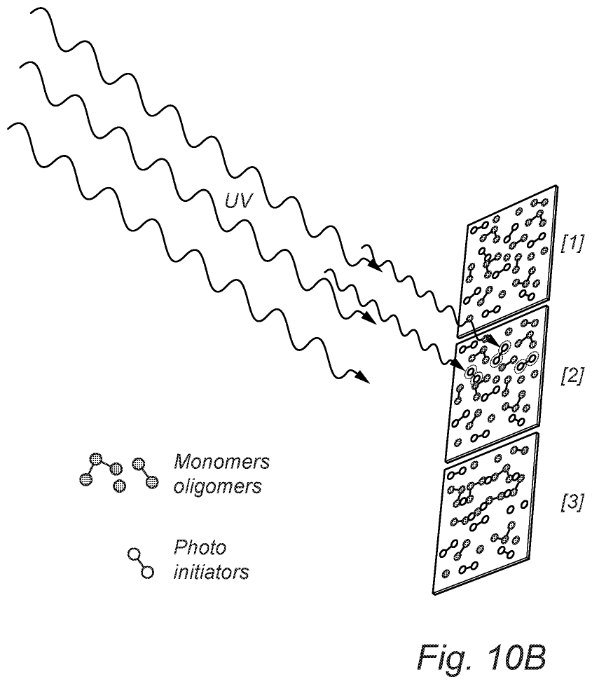

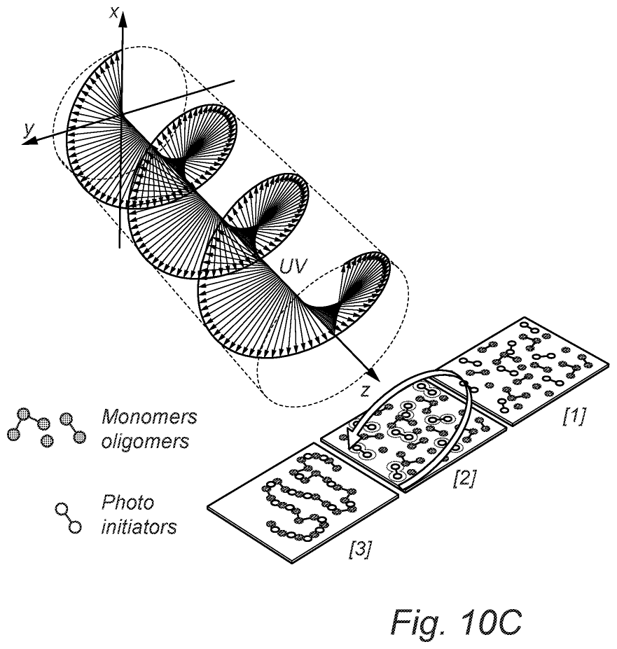

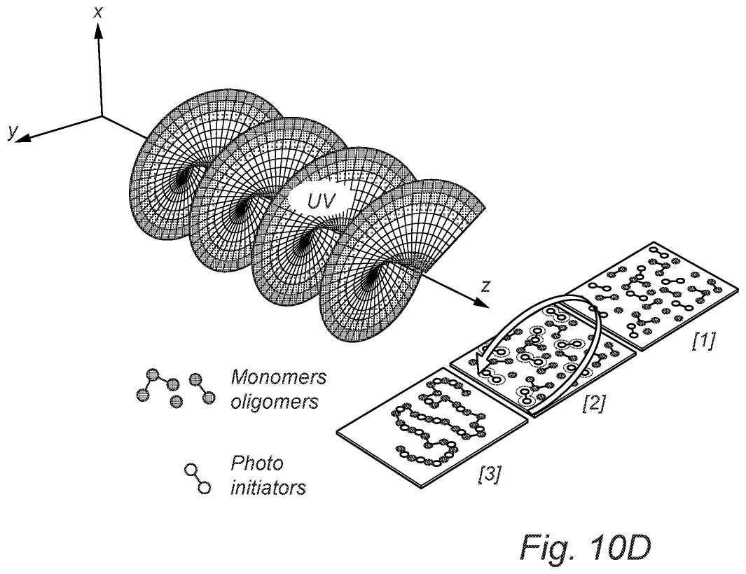

Referring now specifically to FIG. 10, one representation of the conceptualized exchange of optimized spin angular momentum (SAM) [C] and/or optimized orbital angular momentum (OAM) [D] carried by UV photons that interact with matter. In this particular example, matter is represented by a UV curable polymer that results from the linking of monomers, oligomers and UV excited photo initiators. UV curable precursors [A][1], [B][1], [C][1], and [D][1] are inert until UV photons carrying sufficient energy can be absorbed by photoinitiators [B][2], [C][2], and [D][2], which will link monomers and oligomers into a chain of polymers [B][3], [C][3], and [D][3]. UV photons carrying optimized spin angular momentum (SAM) and/or optimized orbital angular momentum (OAM) will transfer their momentum to matter and so increase the probability for photoinitiators to absorb these photons [C][2], and [D][2]. This results in an enhanced polymerization [C][3], and [D][3].

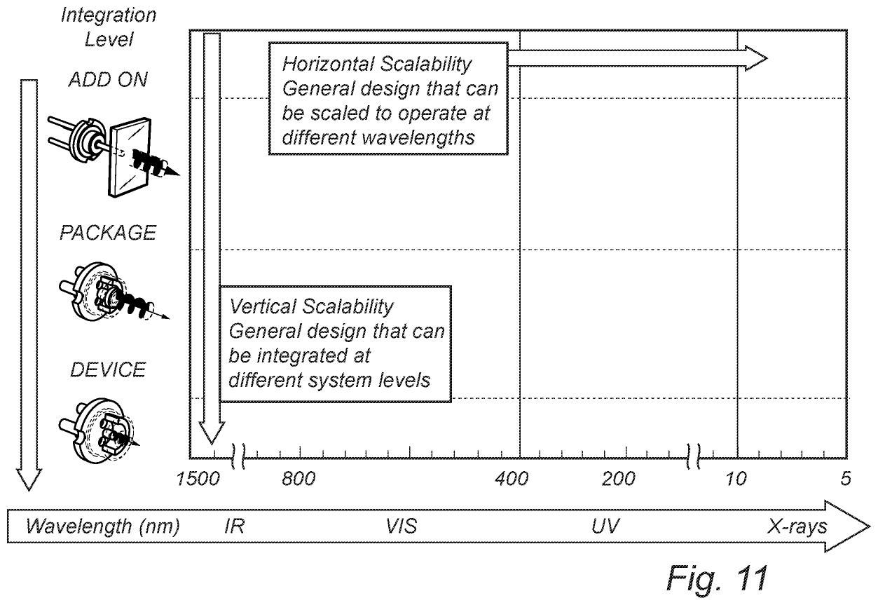

Referring now specifically to FIG. 11, the representation of range of operation of the invention in the UV segment of the electromagnetic spectrum: from 400 nm to 10 nm. Illustrated are also the concept of Horizontal Scalability (HS), and Vertical Scalability (VS). HS implies a general design that can be scaled to operate at different wavelength within said electromagnetic spectrum. VS implies a general design that can integrated at different system levels.

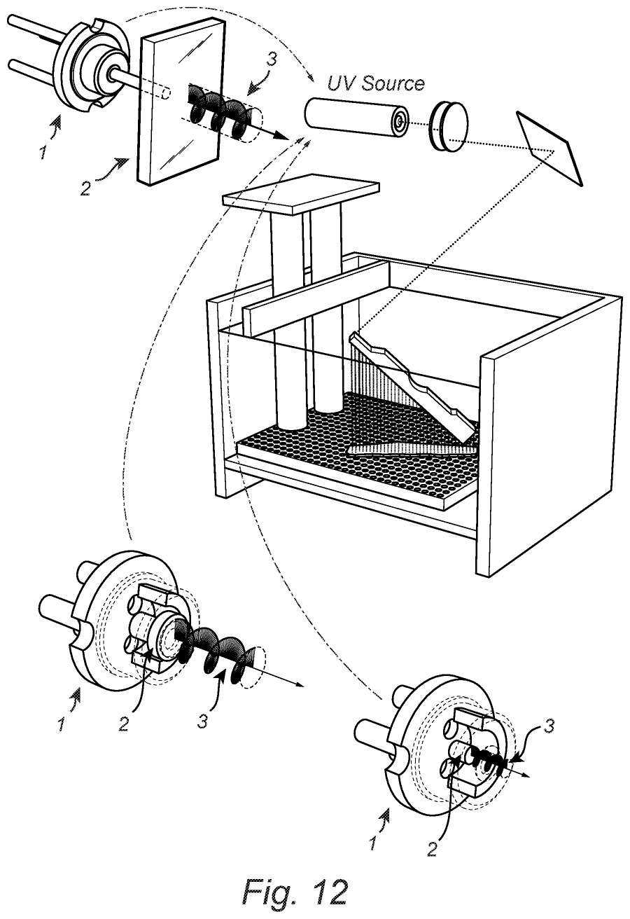

Referring now specifically to FIG. 12, the representation of the use the invention to enable a Right-Side Up SLA 3D printer with the ability to use UV photons carrying engineered angular momentum. Illustrated is also the concept of Vertical Scalability (VS), which implies a general design that can be integrated at different system levels.

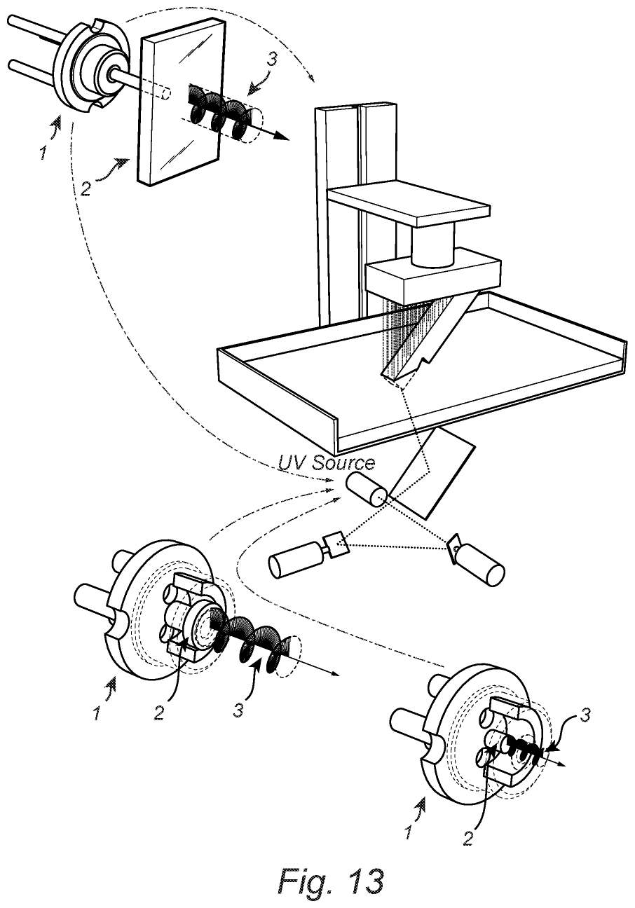

Referring now specifically to FIG. 13, the representation of the use the invention to enable an Inverted SLA 3D printer with the ability to use UV photons carrying engineered angular momentum. Illustrated is also the concept of Vertical Scalability (VS), which implies a general design that can be integrated at different system levels.

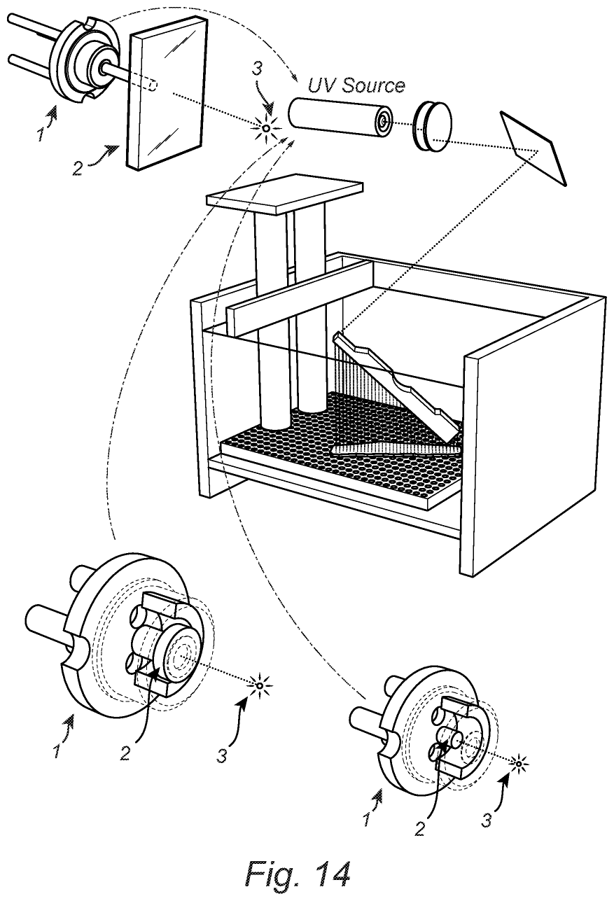

Referring now specifically to FIG. 14, the representation of the use the invention to enable a Right-Side Up SLA 3D printer with the ability to use a super-resolved (sub-wavelength) beam or flux of UV photons to achieve higher resolution, accuracy and precision. Illustrated is also the concept of Vertical Scalability (VS), which implies a general design that can be integrated at different system levels.

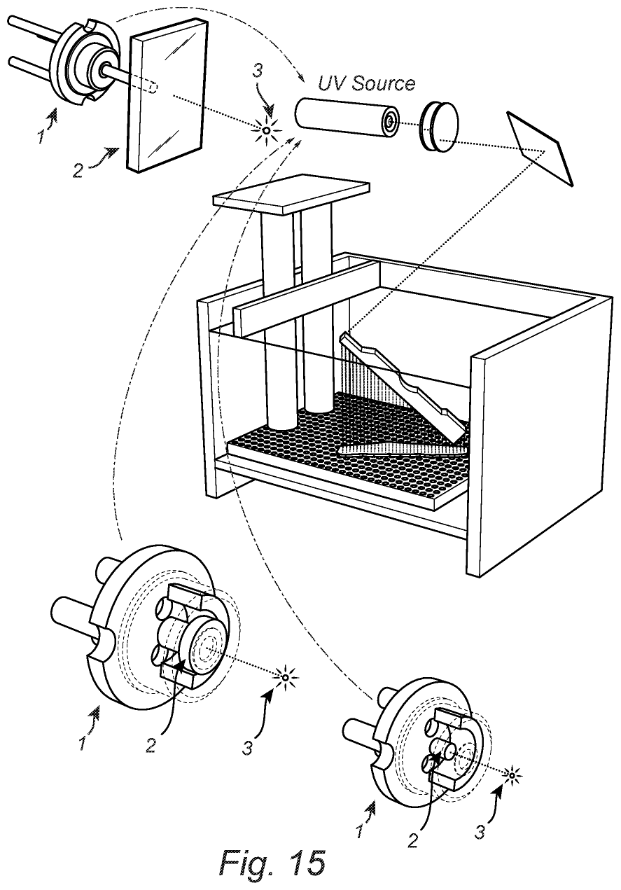

Referring now specifically to FIG. 15, the representation of the use the invention to enable an Inverted SLA 3D printer with the ability to use a super-resolved (sub-wavelength) beam or flux of UV photons to achieve higher resolution, accuracy and precision. Illustrated is also the concept of Vertical Scalability (VS), which implies a general design that can be integrated at different system levels.

One further embodiment of the invention is comprising a source of near-UV and/or UV photons, one or more stand alone angular momentum generators configured to deliver near-UV and/or UV photons with or without optimized spin angular momentum (SAM), or orbital angular momentum (OAM), and/or a combined SAM/OAM, which includes the an algorithm and/or design to achieve super-resolution with near-UV and/or UV radiation (coherent or incoherent), such as the super-resolution algorithm called Prior Discrete Fourier Transformation (PDFT).

One further embodiment of the invention is comprising a source of near-UV and/or UV photons, one or more stand alone angular momentum generators configured to deliver near-UV and/or UV photons with or without optimized spin angular momentum (SAM), or orbital angular momentum (OAM), and/or a combined SAM/OAM, which includes the an algorithm and/or design to achieve super-resolution with near-UV and/or UV radiation (coherent or incoherent), such as [1] lenses designed numerically by modifying a pattern of concentric rings until the target design is obtained, [2] nonlinear design algorithms, which optimize the zone width of domains of constant phase inside the DOE aperture, either matching a finite set of signal samples, or optimizing additional components of a more complex cost function, and/or [3] super-resolution elements based on the concept of super-oscillations.

Although the present invention is illustrated and described herein with reference to preferred embodiments and specific examples thereof, it will be readily apparent to those of ordinary skill in the art that other embodiments and examples may perform similar functions and/or achieve like results. All such equivalent embodiments and examples are within the spirit and scope of the present invention, are contemplated thereby, and are intended to be covered by the following non-limiting claims for all purposes.

What is claimed is:

1. A system for 3D printing utilizing non-UV, near-UV, and/or UV photons with or without engineered angular momentum, which may be organized as shaped flux or flux shaping structures of non-UV photons, near-UV photons, and/or UV photons, the system comprising:
one or more of a coherent source, a partially-coherent source, and an incoherent source of one or more of non-UV photons, near-UV photons, and UV photons; and
one or more flux shaping structures or angular momentum generators, with or without flux shaping, configured to impart the one or more of the non-UV photons, the near-UV photons, and the UV photons with one or more of spin angular momentum (SAM) and orbital angular momentum (OAM);
wherein the one or more flux shaping structures or angular momentum generators, with or without flux shaping, are one or more of fabricated as stand-alone structures, fabricated on a package of the one or more of the coherent source, the partially-coherent source, and the incoherent source, and fabricated as an integral part of the one or more of the coherent source, the partially-coherent source, and the incoherent source.

2. The system of claim 1, further comprising means for obtaining one or more of super-resolution and flux-shaped non-UV photons, near-UV photons, and UV photons one or more of fabricated as a stand-alone structure, fabricated on the package of the one or more of the coherent source, the partially-coherent source, and the incoherent source, and fabricated as an integral part of the one or more of the coherent source, the partially-coherent source, and the incoherent source.

3. The system of claim 1, wherein the one or more angular momentum generators or flux shaping structures comprise one or more Spiral Phase Plates made of a non-UV, near-UV, and/or UV transparent material operable for imparting OAM.

4. The system of claim 1, wherein the one or more angular momentum generators or flux shaping structures comprise one or more computer generated diffraction gratings with groove bifurcation comprising one of a fork hologram, a pitchfork hologram, and a fork-like hologram operable for imparting OAM by passing a flux of electromagnetic radiation having incident circular Lauerre-Gaussian through the computer generated diffraction grating.

5. The system of claim 4, wherein the one or more computer generated diffraction gratings comprise one or more phase filters exhibiting super-resolution or flux shaping capabilities.

6. The system of claim 1, wherein the one or more angular momentum generators or flux shaping structures comprise one or more Q-plates operable for imparting one or more of SAM and OAM.

7. The system of claim 6, wherein the one or more Q-plates are implemented dynamically using one or more of liquid crystals, polymers, and subwavelength gratings.

8. The system of claim 1, wherein the one or more angular momentum generators or flux shaping structures comprise one or more thin single domain magnetic needles approximating a magnetic monopole used to generate an optical vortex operable for imparting OAM.

9. The system of claim 1, wherein the one or more of the coherent source, the partially-coherent source, and the incoherent source comprises one of a non-UV, near-UV, and/or UV Laser, a non-UV, near-UV, and/or UV Light Emitting Diode, and a non-UV, near-UV, and/or UV emitting plasma discharge lamp.

10. The system of claim 1, wherein the one or more angular momentum generators or flux shaping structures comprise a Prior Discrete Fourier Transformation (PDFT) phase filter that exhibits super-resolving and/or flux shaping capabilities configured to deliver a super-resolved and/or flux shaped beam configured to be coupled to an optical fiber.

11. The system of claim 1, wherein the 3D printing comprises one of Right-Side-Up SLA 3D printing, and Inverted SLA 3D printing, and a Non-SLA 3D printing that uses a photochemical reaction to print an object.

12. A system for 3D printing utilizing non-UV, near-UV, and/or UV photons with engineered angular momentum or shaped flux, the system comprising:
one of a coherent source, a partially-coherent source, and an incoherent source of one or more of non-UV photons, near-UV photons, and UV photons;
means for obtaining one or more of super-resolved and flux-shaped non-UV photons, near-UV photons, and super-resolved UV photons; and
one or more angular momentum generators or flux shaping structures configured to impart the one or more of the non-UV photons, the near-UV photons and the UV photons with one or more of spin angular momentum (SAM) and orbital angular momentum (OAM);
wherein the means for obtaining and the angular momentum generators or flux shaping structures are one or more of fabricated as stand-alone structures, fabricated on a package of the one of the coherent source, the partially-coherent source, and the incoherent source, and fabricated as an integral part of the one of the coherent source, the partially-coherent source, and the incoherent source.

13. The system of claim 12, wherein the one or more angular momentum generators or flux shaping structures comprise one or more Spiral Phase Plates made of a non-UV, near-UV, and/or UV transparent material operable for imparting OAM.

14. The system of claim 12, wherein the one or more angular momentum generators or flux shaping structures comprise one or more computer generated diffraction gratings with groove bifurcation comprising one of a fork hologram, a pitchfork hologram, and a fork-like hologram operable for imparting OAM by passing a flux of electromagnetic radiation having incident circular Lauerre-Gaussian through the computer generated diffraction grating.

15. The system of claim 14, wherein the one or more computer generated diffraction gratings comprise one or more phase filters exhibiting super-resolution or flux-shaping capabilities.

16. The system of claim 12, wherein the one or more angular momentum generators or flux shaping structures comprise one or more Q-plates operable for imparting one or more of SAM and OAM.

17. The system of claim 16, wherein the one or more Q-plates are implemented dynamically using one or more of liquid crystals, polymers, and subwavelength gratings.

18. The system of claim 12, wherein the one or more angular momentum generators or flux shaping structures comprise one or more thin single domain magnetic needles approximating a magnetic monopole used to generate an optical vortex operable for imparting OAM.

19. The system of claim 12, wherein the one of the coherent source, the partially-coherent source, and the incoherent source comprises one of a non-UV, near-UV, and/or UV Laser, a non-UV, near-UV, and/or UV Light Emitting Diode, and a non-UV, near-UV and/or UV emitting plasma discharge lamp.

20. The system of claim 12, wherein the one or more angular momentum generators comprise a Prior Discrete Fourier Transformation (PDFT) phase filter that exhibits super-resolving capabilities configured to deliver a super-resolved beam configured to be coupled to an optical fiber.

21. The system of claim 12, wherein the 3D printing comprises one of Right-Side-Up SLA 3D printing, and Inverted SLA 3D printing, and a Non-SLA 3D printing that uses a photochemical reaction to print an object.

22. The system of claim 12, wherein the means for obtaining the one or more of the super-resolved or flux-shaped non-UV, near-UV, and/or UV photons comprises one or more of (a) lenses designed numerically by modifying a pattern of concentric rings until a target design is obtained, (b) lenses designed using a Prior Discrete Fourier Transformation (PDFT) algorithm, (c) lenses designed using a nonlinear design algorithm that optimizes a zone width of domains of constant phase inside an aperture, either matching a finite set of signal samples or optimizing other components, and (d) super-resolution elements based on super-oscillations.

23. The system of claim 12, wherein the non-UV photons, the near-UV photons, and/or the UV photons are used for treatment of organic or inorganic substances and/or impurities resulting in dimerization or alteration of nucleic acids and/or proteins, accelerated or decelerated polymerization rates, altered polymerization characteristics, and/or lowered activation energy of a chemical reaction, nuclear reaction, or other physical phenomena.
